(19) United States
(12) Patent Application Publication
(10) Pub. No.: US 2024/0103084 A1
(43) Pub. Date: Mar. 28, 2024

(54) BATTERY GAUGE CIRCUIT

(71) Applicant: TEXAS INSTRUMENTS INCORPORATED, Dallas, TX (US)

(72) Inventors: Charles SESTOK, Dallas, TX (US); Yevgen BARSUKOV, Richardson, TX (US)

(21) Appl. No.: 18/306,549

(22) Filed: Apr. 25, 2023

Related U.S. Application Data
(60) Provisional application No. 63/408,424, filed on Sep. 20, 2022.

(51) Int. Cl. G01R 31/367; G01R 31/389

(52) U.S. Cl. CPC G01R 31/367; G01R 31/389; G01R 31/3842

(57) ABSTRACT

A circuit includes a processing circuit. The processing circuit is configured to model a battery using a battery model. The battery model includes: a voltage terminal, an RC stage having a first resistor and a first capacitor in parallel, a second resistor, a second capacitor and a ground terminal. The second resistor is coupled between the voltage terminal and the RC stage. The RC stage is coupled between the second resistor and the second capacitor. The second capacitor is coupled between the RC stage and the ground terminal. The processing circuit is also configured to determine a first resistance of the first resistor based on a first ratio of the first resistance to a total battery resistance, determine a second resistance of the second resistor based on a second ratio of the second resistance to the total battery resistance, and determine the total battery resistance.

### CROSS-REFERENCE TO RELATED APPLICATIONS

This application claims priority to U.S. Provisional Application No. 63/408,424, filed Sep. 20, 2022, entitled “Dynamic Impedance Track Apparatus and Method for Battery Gauging with Variable Load Current,” which is hereby incorporated by reference.

### BACKGROUND

Many electrical and electronic systems are powered by batteries. A battery gauge circuit may be provided in battery powered systems to estimate the charge remaining in the battery. Estimated battery charge information provided by the battery gauge circuit can be applied to control system power consumption or provided to a user.

### SUMMARY

In one example, a circuit includes a processing circuit. The processing circuit is configured to model a battery using a battery model. The battery model includes: a voltage terminal, an RC stage having a first resistor and a first capacitor in parallel, a second resistor, a second capacitor and a ground terminal. The second resistor is coupled between the voltage terminal and the RC stage. The RC stage is coupled between the second resistor and the second capacitor. The second capacitor is coupled between the RC stage and the ground terminal. The processing circuit is also configured to determine a first resistance of the first resistor based on a first ratio of the first resistance to a total battery resistance, determine a second resistance of the second resistor based on a second ratio of the second resistance to the total battery resistance, and determine the total battery resistance.

In another example, a method includes determining a first resistance of a first resistor of a battery model based on a first ratio of the first resistance to a total battery resistance. The first resistor is coupled between a voltage terminal of the battery model and an RC stage of the battery model. The method also includes determining a second resistance of a second resistor of the battery model based on a second ratio of the second resistance to the total battery resistance. The second resistor is coupled in parallel with a first capacitor in the RC stage and the RC stage is coupled between the first resistor and a second capacitor of the battery model. The method also includes determining a reference capacitance as a ratio of a maximum charge of the battery to an open circuit voltage of the battery, and determining a first capacitance of the first capacitor based on a third ratio of the first capacitance to the reference capacitance. The method further includes determining the total battery resistance as a root of a quadratic equation, and generating a signal representing power available in the battery based on the battery model.

In a further example, a system includes a battery and a battery gauge circuit coupled to the battery. The battery gauge circuit includes a processing circuit. The processing circuit is configured to model the battery using a battery model. The battery model includes a voltage terminal, an RC stage having a first resistor and a first capacitor in parallel, a second resistor, a second capacitor and a ground terminal. The second resistor is coupled between the voltage terminal and the RC stage. The RC stage is coupled between the second resistor and the second capacitor. The second capacitor is coupled between the RC stage and the ground terminal. The processing circuit is also configured to determine a first resistance of the first resistor based on a first ratio of the first resistance to a total battery resistance, and determine a second resistance of the second resistor based on a second ratio of the second resistance to the total battery resistance. The processing circuit is further configured to determine a reference capacitance as a ratio of a maximum charge of the battery to an open circuit voltage of the battery, determine a first capacitance of the first capacitor based on a third ratio of the first capacitance to the reference capacitance, and determine the total battery resistance as a root of a quadratic equation.

### BRIEF DESCRIPTION OF THE DRAWINGS

FIGS. 1 and 2 are example model circuit diagrams of a battery.

FIG. 3 is a block diagram of an example system that includes a battery gauge circuit.

FIG. 4 is a block diagram of battery model update operations in an example battery gauge circuit.

FIG. 5 is a block diagram of a higher-level view of battery model update operations in an example battery gauge circuit.

FIG. 6 is a flow diagram for an example method for updating battery model parameters.

FIG. 7 is a graph of example load current pulses in an application.

FIG. 8 is a graph showing total resistance of a battery determined using the gauge circuitry described herein with the load current pulses of FIG. 7.

### DETAILED DESCRIPTION

In some cases, circuit models approximate electrical device behavior. One such electrical device is a battery cell or group of battery cells, referred to herein as a battery for simplicity. In some cases, rechargeable batteries power various portable devices, such as laptop computers, mobile phones, power tools, and electric vehicles (EVs). The ability to predict battery behavior while the battery provides a current is useful to control and regulate power provided to such devices. A useful battery model accurately predicts voltage, current, and state-of-charge (SoC) while environmental conditions (e.g., temperature, pressure, humidity) vary, and the battery undergoes charging and discharging cycles.

Battery behavior, while providing a current to a load, depends on battery condition and environmental conditions. The battery condition can be characterized by its SoC, which refers to the level of available charge in the battery, and by its state-of-health (SoH), which refers to an amount (e.g., a percentage) of useful charge/discharge cycles remaining compared to the expected charge/discharge cycles that the battery is capable of.

Environmental conditions including temperature (T), pressure and humidity also impact battery behavior.

FIG. 1 is a circuit diagram of an example model 100 of a battery. In the example of FIG. 1, the model 100 includes a series combination of a capacitor 112 having capacitance C_{S}, a resistor 104 having resistance R_{S}, and three resistor-capacitor (RC) stages 106, 108, and 110. The RC stage 106 includes a resistor 116 having resistance R₁ coupled in parallel with a capacitor 118 having capacitance C₁. The RC stage 108 includes a resistor 120 having resistance R₂ coupled in parallel with a capacitor 122 having capacitance C₂. The RC stage 110 includes a resistor 124 having resistance R₃ coupled in parallel with a capacitor 126 having capacitance C₃.

The resistor 104 is coupled between a voltage terminal 102 and the RC stage 106. The RC stage 106 is coupled between the resistor 104 and the RC stage 108. The RC stage 108 is coupled between the RC stage 106 and the RC stage 110. The RC stage 110 is coupled between the RC stage 108 and the capacitor 112. The capacitor 112 is coupled between the RC stage 110 and a ground terminal 114.

The series capacitor 112 represents a charge stored in the battery represented by the model 100. The series resistor 104 represents a high-frequency resistance of the battery represented by the model 100. Each RC stage represents a time constant for the variation of instantaneous voltage of the battery represented by the model 100.

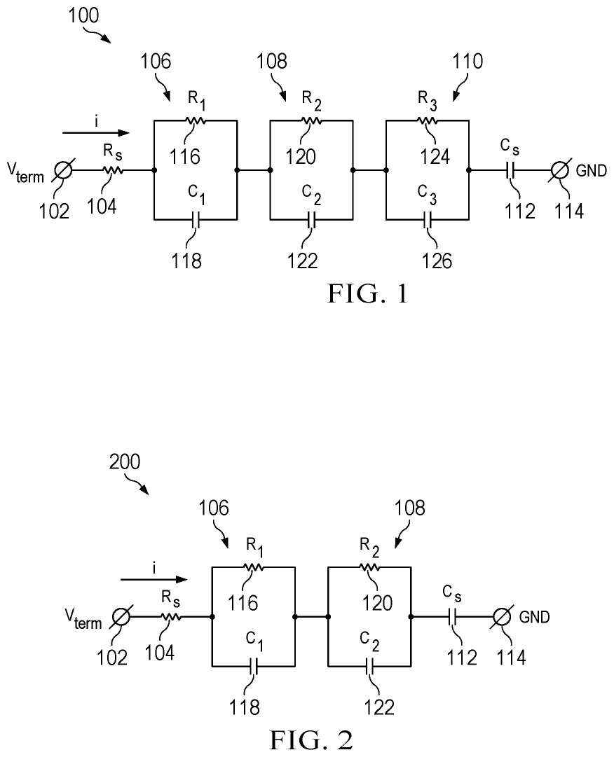

FIG. 2 is a circuit diagram of another example model 200 of a battery. The model 200 is similar to the model 100, but includes two RC stages rather than three RC stages.

For example, the model 200 lacks the RC stage 110 provided in the model 100. In the model 200, the resistance R_{S} may include the resistance R₃ of the resistor 124 in the model 100.

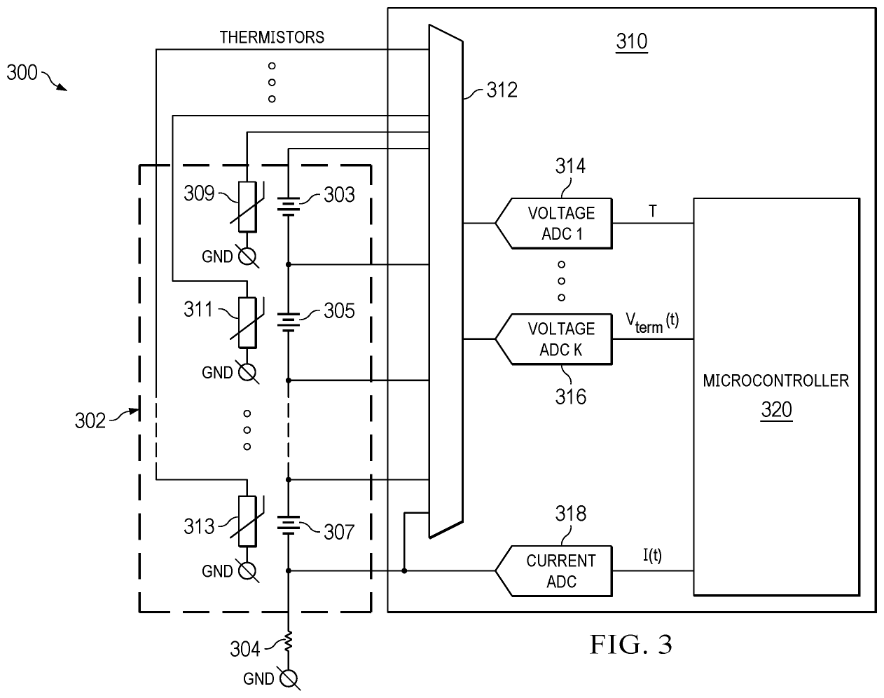

FIG. 3 is a block diagram of an example system 300 that includes a battery gauge circuit 310. The battery gauge circuit 310 may be implemented as an integrated circuit in some examples. The battery gauge circuit 310 is coupled to a battery pack 302 and a sense resistor 304. The battery pack 302 may include multiple battery cells (referred to as batteries herein) in series. Batteries 303, 305, and 307 are shown in FIG. 3. Examples of the battery pack 302 may include any number of batteries coupled in series. The battery 303, the battery 305, and the battery 307 may include multiple battery cells coupled in parallel. The battery pack 302 may also include one or more temperature sensors for measuring the temperature of the batteries. Temperature sensors 309, 311, and 313 are shown in FIG. 3. A temperature sensor may be provided to measure the temperature of each battery. For example, temperature sensors 309, 311, and 313 may be provided to measure the temperatures of the battery 303, the battery 305, and the battery 307, respectively. The temperatures sensors 308, 311, and 313 may include a thermistor or other temperature transducer.

The battery gauge circuit 310 includes a multiplexer 312, analog-to-digital converters (ADCS) 314, 316, and 318, and a microcontroller 320. The multiplexer 312 selects the signals provided to the ADC 314 and the ADC 316 for digitization. The multiplexer 312 may select the voltage across one of the batteries of the battery pack 302 and/or the voltage across one of the temperature sensors to provide to the ADC 314 and the ADC 316 for digitization. The ADC 314 and the ADC 316 may be implemented as differential ADCS in some examples of the battery gauge circuit 310. Inputs of the multiplexer 312 are coupled to battery voltage and temperature sensor outputs of the battery pack 302. Outputs of the multiplexer 312 are coupled to inputs of the ADC 314 and the ADC 316. The ADC 314 and the ADC 316 digitize the signals received from the multiplexer 312 and provide the digital signals to the microcontroller 320. Some implementations of the battery gauge circuit 310 may include more or fewer ADCS for digitizing battery pack output signals than are shown in FIG. 3.

The voltage (current sense signal) across the sense resistor 304 is proportional to the current flowing through the battery pack 302. The sense resistor 304 is coupled between the battery pack 302 and a ground terminal. An input of the ADC 318 is coupled to the sense resistor 304. An output of the ADC 318 is coupled to the microcontroller 320. The ADC 318 digitizes the current sense signal and provides the digitized signal to the microcontroller 320.

The microcontroller 320 executes instructions stored in a memory of the microcontroller 320 (e.g., a non-transient computer-readable medium) to model the batteries 303, 305, and 307 according to the model 100 or the model 200, and to determine various parameters of the batteries, such as SoC, SoH, and/or time until discharged. The microcontroller 320 determines the values of the parameters of the battery model based on the measurement signals provided by the ADCS and stored battery parameters. The stored battery parameters include values that remain relatively constant over the life of the battery. The values include ratios of model resistor resistance to total battery resistance, and ratios of model capacitor capacitance to a reference capacitance. The microcontroller 320 may determine the total battery resistance by solving an equation dependent on the measurement signals (provided by the ADCS 314, 316, 318) and stored battery parameters.

The microcontroller 320 may determine the reference capacitance based on the total charge storage capacity of a given battery. Some implementations of the battery gauge circuit 310 may include dedicated circuitry (an application specific circuit) that determine the parameters of the battery model, rather than, or in addition to, the microcontroller 320.

The battery gauge circuit 310 and the battery pack 302 may also be coupled to a load circuit (not shown) that is powered by the battery pack 302. For example, a load circuit coupled to the battery pack 302 may include a motor control circuit and electric motor.

Current consumed by the load circuit may be controlled based on the parameters of the batteries of the battery pack 302 determined by the battery gauge circuit 310 and communicated to the load circuit. Some battery gauge circuits may be unable to accurately model the battery parameters when used with a load circuit that draws a widely varying current from the battery pack 302 (e.g., a motor that intermittently draws a high load current). The battery gauge circuit 310 more accurately models batteries with pulsed load currents to provide more accurate SoC, SoH, discharge time estimates, and other battery parameters which allows for more precise control of the load circuit based on battery state information.

Table 1 shows examples of the various parameters applied in the microcontroller 320 to model the batteries.

TABLE 1

| | | ADC Measured |
|---|---|---|
| Stored Parameters | Estimated Parameters | Parameters |
| OCV: Open Circuit Voltage | DoD: Degree of Discharge | i(t): current |
| (across Cₛ) | (0 ≤ DoD ≤ 1) | |
| β_{C}_{ₖ}: Normalized RC Stage | R_{LF}: Low-frequency | Vₜₑᵣₘ(t): terminal |
| Capacitances | Resistance, 25° C. | voltage |
| γ_{R}_{ₖ}: RC Stage Resistance Ratio | Vₖ: RC Stage Capacitor | T: temperature |
| to R_{LF}, 25° C. | Voltages | |
| γ_{R}_{ₛ}: Series Resistance Ratio to | Qₘₐₓ: Charge Storage | |
| R_{LF}, 25° C. | Capacity | |
| R_{bk, l}: Battery Resistance Temp. | | |
| Coefficient 0-25° C | | |
| R_{bk, h}: Battery Resistance Temp. | | |
| Coefficient 25-50° C | | |
| τ_{Temp}: Battery Cell Thermal Time | | |
| Constant | | |
| k_{Temp}: Battery Cell I²R Heating | | |
| Temperature Gain | | |
| Qₘₐₓ_{_{—}}ᵢₙᵢₜ: Initial Charge Storage | | |
| Capacity | | |

β_{C}_{ₖ} may be determined as:

$${β}_{{c}_{k}} = \frac{{c}_{k} ( DoD , T )}{{c}_{ref ( DoD , T , Qmax )}} \qquad ( 1 )$$

where:
Cₖ is capacitance C₁, C₂, or C₃.
C_{ref} is a reference capacitance (derivation of C_{ref} is described herein).

R_{LF} is the total resistance of the model 100:

R_{LF}=Rₛ+Σₖ₌₁³Rₖ (2)

wherein Rₖ is R₁, R₂, or R₃.

The RC stage resistance ratio is:

$${γ}_{{R}_{k}} = \frac{{R}_{k}}{{R}_{LF}} \qquad ( 3 )$$

The series resistance ratio is:

$${γ}_{{R}_{s}} = \frac{{R}_{s}}{{R}_{LF}} \qquad ( 4 )$$

The stored parameters of Table 1 may be computed from RC circuit base battery models. The behavior of the battery at a known DoD is modeled by a battery model RC circuit, such as the model 100. The stored ratio parameters defined in equations (1) and (3) are computed from the battery model parameters. They are estimated from the measured terminal voltage in response to a known current drawn from the battery. Load currents used for battery characterization are often composed of a sequence of constant current pulses, or a sum of sinusoidally varying load currents with known frequencies. For the current pulse load current, the battery terminal voltage is measured during an interval between pulses. A non-linear least-squares parameter estimation algorithm may be used to determine the parameters of the RC circuit that best describes the battery behavior. For sinusoidally varying load currents, the battery impedance is computed at each excitation frequency. A non-linear least-squares parameter estimation algorithm may be used to determine the parameters of the RC circuit that best matches the measured impedance spectrum.

The temperature coefficients of the resistance parameters of the battery model, expressed by R_{b,l} and R_{b,h}, are determined from battery models measured at three different ambient temperatures. A representative set of values are T_{low}=0° C., T_{mid}=25° C., and T_{high}=50° C. The low and high temperature are given by the operating limits of the battery, and the central temperature is room temperature. The temperature variation of the resistance is modeled as exponential, as seen in Equations 20-23. The parameters R_{bk,l} and R_{bk,h} are computed to provide a best fit of the measured data at T_{low}, T_{mid}, and T_{high}, according to these models.

The thermal time constant and heating gain are determined from the battery temperature sensor 309-313 measurements made during a constant current pulse. They may be computed using a non-linear least-squares parameter estimation algorithm.

The RC stage resistance ratios and the series resistance ratio remain relatively constant (change very slowly) over the useful life of the battery. Additionally, the RC stage capacitance ratios remain relatively constant over useful the life of the battery.

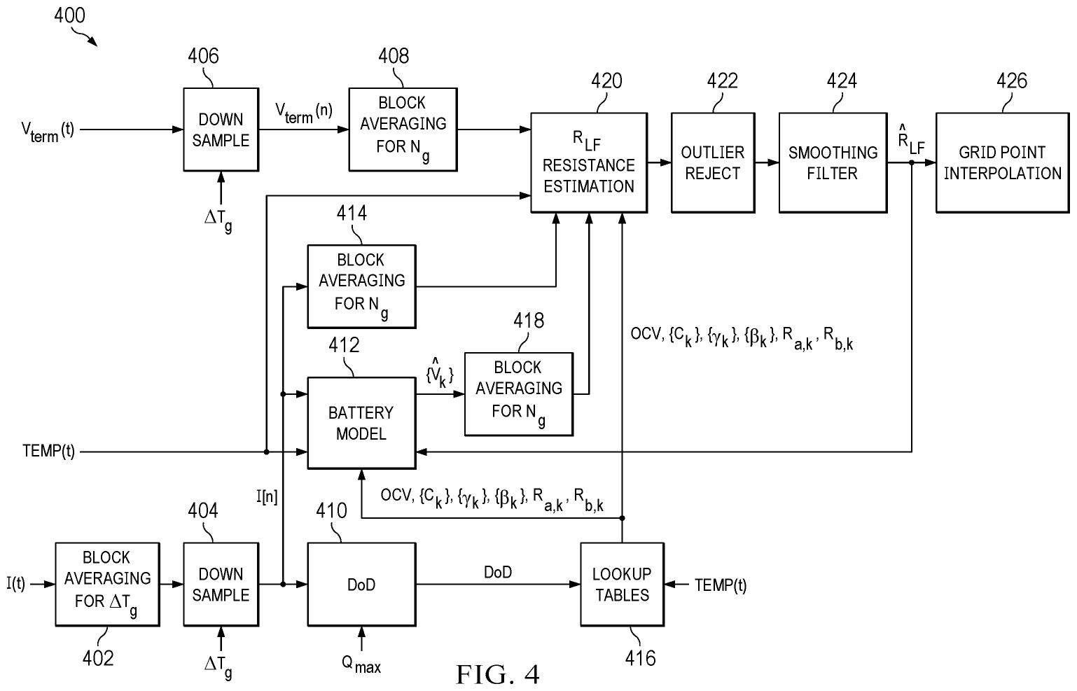

FIG. 4 is a block diagram of example processing circuitry 400 of the battery gauge circuit 310 used to model the batteries. The circuitry of FIG. 4 may be implemented by the microcontroller 320 or by dedicated hardware. Inputs to the circuitry include battery voltage Vₜₑᵣₘ(t), battery temperature Temp(t), and battery current I(t) provided by the ADCS 314, 316, and 318. A block averaging circuit 402 receives and averages I(t) over an interval ΔT_{g}. For example, the block averaging circuit 402 generates a moving average of the I(t) over an interval ΔT_{g}. A down sampling circuit 404 receives the average current values provided by the block averaging circuit 402 and down samples the I(t) to a sample rate defined by ΔT_{g}. The down sampled current is denoted I[n]. I[n] is provided to a degree of discharge (DoD) circuit 410, a battery model circuit 412, and an averaging circuit 414. The averaging circuit 414 averages the down sampled current I[n] over an interval defined by N_{g}.

$${i}_{a v g} = \frac{1}{{N}_{9}} {\sum }_{n = 1}^{{N}_{9}} i [ n ] \qquad ( 5 )$$

The DoD circuit 410 provides a DoD value representing an amount of energy drained from the battery (e.g., as a percentage of the total battery energy storage capacity). The DoD circuit 410 may also provide a value of SoC as SoC=1−DoD. The DoD circuit 410 may determine DoD based on the maximum charge of the battery (charge stored when the battery is fully charged), which may be expressed as:

$${Q}_{max} = \frac{{Q}_{passed}}{Δ D o D} = \frac{{\int }_{{t}_{1}}^{{t}_{2}} i ( t ) dt}{DoD ( OCV ( {t}_{2} ) ) - DoD ( OCV ( {t}_{1} ) )} \qquad ( 6 )$$

where:
Q_{passed} is current drawn from the battery over a time interval (e.g., t₁ to t₂); and ΔDoD is the difference in DoD with the open circuit voltage (OCV) at t₁ and t₂.

The DoD circuit 410 may update DoD as:

$$DoD [ n + 1 ] = DoD [ n ] - \frac{Δ {T}_{samp}}{{Q}_{max}} i [ n ] \qquad ( 7 )$$

where ΔTₛₐₘₚ is the sampling interval.

Lookup tables 416 store the stored parameters listed in Table 1 and provide the stored parameters based on DoD received from the DoD circuit 410 and Temp(t).

A down sampling circuit 406 receives and down samples Vₜₑᵣₘ(t) to a sample rate defined by ΔT_{g}. The down sampled Vₜₑᵣₘ(t) is denoted Vₜₑᵣₘ[n]. The averaging circuit 408 averages the down sampled voltage Vₜₑᵣₘ[n] over an interval defined by N_{g}.

$${V}_{term , avg} = \frac{1}{{N}_{g}} {\sum }_{n = 1}^{{N}_{g}} {V}_{term} [ n ] \qquad ( 8 )$$

The battery model circuit 412 determines the parameters of the model 100 or the model 200 (e.g., resistance and capacitance values, capacitor voltages) based on I[n], Temp(t), the stored parameters provided by the lookup tables 416, and the total resistance R_{LF} of the battery model. The battery model circuit 412 may determine the series resistance Rₛ and the RC stage resistance Rₖ of the battery model according to equations (3) and (4). Given Rₖ, the battery model circuit 412 may update the voltages Vₖ across the RC stages as:

Vₖ[n+1]=Vₖ[n]e^{-ΔT}^{ₛₐₘₚ}^{/R}^{ₖ}^{C}^{ₖ}+(1−e^{-ΔT}^{ₛₐₘₚ}^{/R}^{ₖ}^{C}^{ₖ})Rₖi[n] (9)

where:

Rₖ=R_{LF}γ_{R}_{ₖ}(DoD)e^{R}^{_{b,k}}^{(DoD)T};

Cₖ=Cₖ(DoD,T); and

e^{R}^{_{b,k}}^{(DoD)T} is an exponential function for temperature adjustment.

The battery model circuit 412 may also approximate Vₖ updates as:

$${V}_{k} [ n + 1 ] \approx {V}_{k} [ n ] ( 1 - \frac{Δ {T}_{samp}}{{R}_{k} {C}_{k}} ) + ( \frac{Δ {T}_{samp}}{{C}_{k}} ) i [ n ] \qquad ( 10 )$$

where:

$$Δ {T}_{samp} ≪ {min}_{k} {R}_{LF} {γ}_{{R}_{k}} ( DoD ) {e}^{{R}_{b , k} ( DoD ) T} {C}_{k} ;$$

ΔTₛₐₘₚ is the ADC sampling interval; and
Cₖ are the RC stage capacitance values.

The battery model circuit 412 provides Vₖ estimates (\hat{V}ₖ) to an averaging circuit 418. The averaging circuit 418 averages the \hat{V}ₖ over an interval defined by N_{g}.

$${V}_{k , avg} = \frac{1}{{N}_{g}} {\sum }_{n = 1}^{{N}_{g}} {V}_{k} [ n ] \qquad ( 11 )$$

The averaging circuit 418 provides the average values to the resistance (R_{LF}) estimation circuit 420. The R_{LF} estimation circuit 420 applies the average Vₜₑᵣₘ[n] value received from the averaging circuit 408, Temp(t), the average I[n] value received from the averaging circuit 414, the average \hat{V}ₖ values received from the averaging circuit 418, and various stored parameter value received from the lookup tables 416 to determine a value of total resistance (R_{LF}) of the battery model. The R_{LF} estimation circuit 420 may solve a quadratic equation to determine a value of R_{LF}. The quadratic equation applied to determine R_{LF} may be derived as follows.

Starting with the terminal voltage equation:

Vₜₑᵣₘ[n]=OCV[n]+Σₖ₌₁³Vₖ[n]+Rₛi[n] (12)

where Rₛ=R_{LF}γ_{R}_{ₛ}(DoD)e^{R}^{_{b,s}}^{(DoD)T}.
Substituting in the RC stage capacitor voltage approximations of equation (10):

$${V}_{term} [ n + 1 ] = OCV [ n + 1 ] + {\sum }_{k = 1}^{3} ( {V}_{k} [ n ] ( 1 - \frac{Δ {T}_{samp}}{{R}_{k} {C}_{k}} ) + ( \frac{Δ {T}_{samp}}{{C}_{k}} ) i [ n ] ) + {R}_{s} i [ n + 1 ] \qquad ( 13 )$$

The RC stage resistances can be expressed in terms of R_{LF}:

$${V}_{term} [ n + 1 ] = OCV [ n + 1 ] + {\sum }_{k = 1}^{3} ( {V}_{k} [ n ] ( 1 - \frac{Δ {T}_{samp}}{{R}_{LF} {γ}_{{R}_{k}} {e}^{{R}_{b , k} T} {C}_{k}} ) + ( \frac{Δ {T}_{samp}}{{C}_{k}} ) i [ n ] ) + {R}_{LF} {γ}_{{R}_{s}} {e}^{{R}_{b , s} T} i [ n + 1 ] \qquad ( 14 )$$

Both sides of equation (14) are multiplied by R_{LF} to produce the quadratic equation used by the R_{LF} estimation circuit 420 to determine R_{LF}:

$${R}_{LF}^{2} {γ}_{{R}_{s}} {e}^{{R}_{b , s} T} i [ n + 1 ] + {R}_{LF} ( OCV [ n + 1 ] - {V}_{term} [ n + 1 ] + {\sum }_{k = 1}^{3} ( {V}_{k} [ n ] + ( \frac{Δ {T}_{samp}}{{C}_{k}} ) i [ n ] ) - ( {\sum }_{k = 1}^{3} \frac{Δ {T}_{samp}}{{γ}_{{R}_{k}} {e}^{{R}_{b , k} T} {C}_{k}} {V}_{k} [ n ] ) = 0 \qquad ( 15 )$$

In some implementations of the R_{LF} estimation circuit 420, the quadratic equation used to determine R_{LF} (e.g., equation 15) may be modified to provide voltage sampling in the middle of a current sampling interval.

$${R}_{LF}^{2} {γ}_{{R}_{s}} i [ n ] + {R}_{L} ( ( \frac{OCV [ n + 1 ] + OCV [ n ]}{2} ) - {V}_{term} [ n + \frac{1}{2} ] + {\sum }_{k = 1}^{3} ( {V}_{k} [ n ] + ( \frac{Δ {T}_{samp}}{2 {C}_{k}} ) i [ n ] ) ) - ( {\sum }_{k = 1}^{3} \frac{Δ {T}_{samp}}{2 {γ}_{{R}_{k}} {C}_{k}} {V}_{k} [ n ] ) = 0 \qquad ( 16 )$$

With the averaged voltage and current measurements provided in the processing circuitry 400, equation (15) may be expressed as:

$${R}_{LF}^{2} {γ}_{{R}_{s}} {e}^{{R}_{b , s} T} {i}_{avg} + {R}_{LF} ( {OCV}_{avg} - {V}_{term , avg} + {\sum }_{k = 1}^{3} ( {V}_{k , avg} + ( \frac{Δ {T}_{samp}}{{C}_{k}} ) {i}_{avg} ) ) - ( {\sum }_{k = 1}^{3} \frac{Δ {T}_{samp}}{{γ}_{{R}_{k}} {e}^{{R}_{b , k} T} {C}_{k}} {V}_{k , avg} ) = 0 \qquad ( 17 )$$

where:
i_{avg} is the output of the averaging circuit 414;
OCV_{avg} is provided by the lookup tables 416;
V_{term.avg} is provided by the averaging circuit 408; and
V_{k.avg} is provided by the averaging circuit 418.

The quadratic equation solved by the R_{LF} estimation circuit 420 to determine R_{LF} has two candidate roots {\hat{R}_{LF,1}, \hat{R}_{LF,2}}. The R_{LF} estimation circuit 420 selects one of the two roots as R_{LF}. In some examples, only one of the two roots is positive, in which case the R_{LF} estimation circuit 420 selects the positive root to be R_{LF}. In a case of two positive roots, the R_{LF} estimation circuit 420 may select the root closest to a previous value of R_{LF} (a previous R_{LF} value produced by filtering) to be the new R_{LF} value. In a case of two negative roots or two zero roots, the R_{LF} estimation circuit 420 may discard both roots, and the value of R_{LF} is not updated (a previously determined value of R_{LF} is applied).

The R_{LF} estimation circuit 420 provides the root value selected to be R_{LF} to the outlier rejection circuit 422. The outlier rejection circuit 422 applies thresholds based on prior values of R_{LF} determined over a selected time interval to identify and reject R_{LF} values outside of a range of acceptable values. The R_{LF} estimation circuit 420 may determine the maximum and minimum R_{LF} thresholds defining the range of acceptable values as:

$${R}_{LF , MaxThresh} ( t ) = α ( {max}_{0 \leq τ \leq 50 S} {R}_{LF} ( t - Δ {T}_{samp} - τ ) ) \qquad ( 18 )$$

$${R}_{LF , MinThresh} ( t ) = {α}^{- 1} ( {max}_{0 \leq τ \leq 50 S} {R}_{LF} ( t - Δ {T}_{samp} - τ ) ) \qquad ( 19 )$$

where: α>1.

The outlier rejection circuit 422 may replace values of R_{LF} outside of the acceptable range with the threshold values. A value of R_{LF} greater than the maximum R_{LF} threshold may be replaced by the value of the maximum R_{LF} threshold. A value of R_{LF} less than the minimum R_{LF} threshold may be replaced by the value of the minimum R_{LF} threshold. In some examples, the R_{LF} may not be updated if the candidate value is outside of the acceptable range.

The outlier rejection circuit 422 provides R_{LF} values to the smoothing filter 424. The smoothing filter 424 may be implemented as an infinite impulse response (IIR) low-pass filter (e.g., 10 second time constant). The smoothing filter 424 provides filtered values of R_{LF} to the battery model circuit 412 for use in determining the series and RC stage resistance values of the battery model. The smoothing filter 424 also provides the filtered values of R_{LF} to a grid point interpolation circuit 426.

The grid point interpolation circuit 426 estimates parameters of a linear model for the battery resistance as a function of DoD. It is intended to reduce errors in the resistance estimate due to rapid changes in the load current. The grid points are a set of DoD values chosen to capture the behavior of the total battery resistance R_{LF}. Generally, the total resistance changes more quickly as the battery nears fully discharged. To capture this effect, the DoD spacing between grid points is smaller for DoD above 80%. As the battery is discharged, the resistance estimates R_{LF}(DoD) are computed and the DoD is tracked using a variety of methods. The behavior of the total resistance in the vicinity of a grid point denoted by DoD, is modeled as a linear function, e.g., R_{LF}(DoD)≈R_{LF}(DoDₚ)+m(DoD−DoDₚ), where m denotes the slope and R_{LF}(DoDₚ) denotes the intercept of the line. The grid point interpolation circuit estimates the slope and intercept of a line modeling the total resistance as a function of DoD The estimates are generated from pairs of \hat{R}_{LF} and the corresponding DoD, when DoD is in an interval near the grid point DoDₚ. When the value of DoD is outside the interval used for interpolation, the total resistance is estimated by interpolation between the intercept parameters for a pair of grid points, R_{LF}(DoDₚ) and R_{LF}(DoDₚ₊₁).

The resistance estimate generated by this interpolation can be combined with the resistance and capacitance ratio parameters to generate a battery model based on an RC equivalent circuit. The battery model can be used to predict the behavior of the battery in response to load currents. In gauging applications, the battery model based on the resistance estimates is used to predict when the maximum current that can be drawn while maintaining the battery terminal voltage above its minimum value, or the amount of time remaining until the battery terminal voltage reaches its minimum value when a known, periodic load current is drawn from the battery.

The battery model circuit 412 applies R_{LF} provided by the smoothing filter 424 to determine the values of the resistors of the battery model. The battery model circuit 412 may determine the resistances as:

$${R}_{s} ( DoD , T ) = \{ \begin{matrix}{R}_{LF} ( DoD ) {γ}_{{R}_{s}} ( DoD , 25 ° C . ) {e}^{{R}_{bs , low} ( DoD ) T} , & T < 25 ° C . \\ {R}_{LF} ( DoD ) {γ}_{{R}_{s}} ( DoD , 25 ° C . ) {e}^{{R}_{bs , high} ( DoD ) ( T - 25 )} , & T \geq 25 ° C .\end{matrix} \qquad ( 20 )$$

$${R}_{1} ( DoD , T ) = \{ \begin{matrix}{R}_{LF} ( DoD ) {γ}_{{R}_{1}} ( DoD , 25 ° C . ) {e}^{{R}_{b 1 , low} ( DoD ) T} , & T < 25 ° C . \\ {R}_{LF} ( DoD ) {γ}_{{R}_{1}} ( DoD , 25 ° C . ) {e}^{{R}_{b 1 , high} ( DoD ) ( T - 25 )} , & T \geq 25 ° C .\end{matrix} \qquad ( 21 )$$

$${R}_{2} ( DoD , T ) = \{ \begin{matrix}{R}_{LF} ( DoD ) {γ}_{{R}_{2}} ( DoD , 25 ° C . ) {e}^{{R}_{b 2 , low} ( DoD ) T} , & T < 25 ° C . \\ {R}_{LF} ( DoD ) {γ}_{{R}_{2}} ( DoD , 25 ° C . ) {e}^{{R}_{b 2 , high} ( DoD ) ( T - 25 )} , & T \geq 25 ° C .\end{matrix} \qquad ( 22 )$$

$${R}_{3} ( DoD , T ) = \{ \begin{matrix}{R}_{LF} ( DoD ) {γ}_{{R}_{3}} ( DoD , 25 ° C . ) {e}^{{R}_{b 3 , low} ( DoD ) T} , & T < 25 ° C . \\ {R}_{LF} ( DoD ) {γ}_{{R}_{3}} ( DoD , 25 ° C . ) {e}^{{R}_{b 3 , high} ( DoD ) ( T - 25 )} , & T \geq 25 ° C .\end{matrix} \qquad ( 23 )$$

where:
γ_{Rx} represents the ratio of the selected resistance (Rₓ) to the total resistance (R_{LF}) of the battery at a selected temperature (e.g., 25° Celsius (C));
R_{bx,low} controls temperature-based adjustment of resistance responsive to measured temperature below a threshold (e.g., <25° C.); and
R_{bx,high} controls temperature-based adjustment of resistance responsive to measured temperature above a threshold (e.g., 25° C.);

In some implementations of the processing circuitry 400, the resistance ratios may be factored into gain and offset to reduce the storage needed.

γ_{R}_{ₖ}(DoD,T)=γ_{R}_{_{k,gain}}(T)γ_{R}_{_{k,offset}}(DoD,T) (24)

The lookup tables 416 may determine the capacitance values of the battery model based on a reference capacitance (C_{ref}). The reference capacitance may be based on maximum battery charge (Qₘₐₓ). the lookup tables 416 may determine C_{ref} as:

$${C}_{ref} ( DoD , T , {Q}_{max} ) = \frac{{Q}_{max} \times SoC}{OCV ( SoC )} , or \qquad ( 25 )$$

$${C}_{ref} ( DoD , T , {Q}_{max} ) = \frac{{Q}_{max} \times SoC}{OCV ( SoC )} \qquad ( 26 )$$

The lookup tables 416 may determine the capacitances of the battery model as:

Cₖ(DoD,T)=β_{C}_{ₖ}(DoD,T)C_{ref}(DoD,T,Qₘₐₓ) (27)

To reduce parameter storage, the ratio βck may be stored as gain and offset, and the product thereof applied to determine Cₖ.

β_{C}_{ₖ}_{,total}(DOD,T)=β_{C}_{ₖ}_{,gain}(T)β_{C}_{ₖ}_{,offset}(DoD,T) (28)

Cₖ(DOD,T)=β_{C}_{ₖ}_{,total}(DoD,T)C_{ref}(DoD,T,Qₘₐₓ) (29)

The lookup tables 416 may apply a linear interpolation between capacitance values to model temperature dependence.

$${C}_{k} ( DoD , T ) = \{ \begin{matrix}{C}_{k} ( DoD , 0 ° C . ) + \frac{T}{25 ° C .} ( \begin{matrix}{C}_{k} ( DoD , 25 ° C . ) - \\ {C}_{k} ( DoD , 0 ° C . )\end{matrix} ) , & T < 25 ° C . \\ {C}_{k} ( DoD , 25 ° C . ) + \frac{T - 25 ° C .}{25 ° C .} ( \begin{matrix}{C}_{k} ( DoD , 50 ° C . ) - \\ {C}_{k} ( DoD , 25 ° C . )\end{matrix} ) , & T \geq 25 ° C .\end{matrix} \qquad ( 30 )$$

In implementations of the processing circuitry 400 that apply the model 200, the resistors combined to form the resistor 104 (e.g., the resistors 104 and 124 of the model 100) have different temperature coefficients. To account for the different temperature coefficients, the lookup tables 416 may store separate temperature coefficients for the two resistors. The R_{LF} estimation circuit 420 may determine the value of R_{LF} for the model 200 using the two separate temperature coefficients based on equation (15) adjusted as:

$${R}_{LF}^{2} ( {γ}_{{R}_{s}} {e}^{{R}_{b , s} T} + {γ}_{{R}_{3}} {e}^{{R}_{b , 3} T} ) {i}_{avg} + {R}_{LF} ( {OCV}_{avg} - {V}_{term , avg} + {\sum }_{k = 1}^{2} ( {V}_{k , avg} + ( \frac{Δ {T}_{samp}}{{C}_{k}} ) {i}_{avg} ) ) - ( {\sum }_{k = 1}^{2} \frac{Δ {T}_{samp}}{{γ}_{{R}_{k}} {e}^{{R}_{b , k} T} {C}_{k}} {V}_{k , avg} ) = 0 \qquad ( 31 )$$

where:
e^{R}^{_{b,s}}^{T} provides temperature compensation for the resistor 104 of the model 100;
e^{R}^{_{b,3}}^{T} provides temperature compensation for the resistor 124 of the model 100; and
e^{R}^{_{b,k}}^{T} provides temperature compensation for the resistor 116 and the resistor 120.

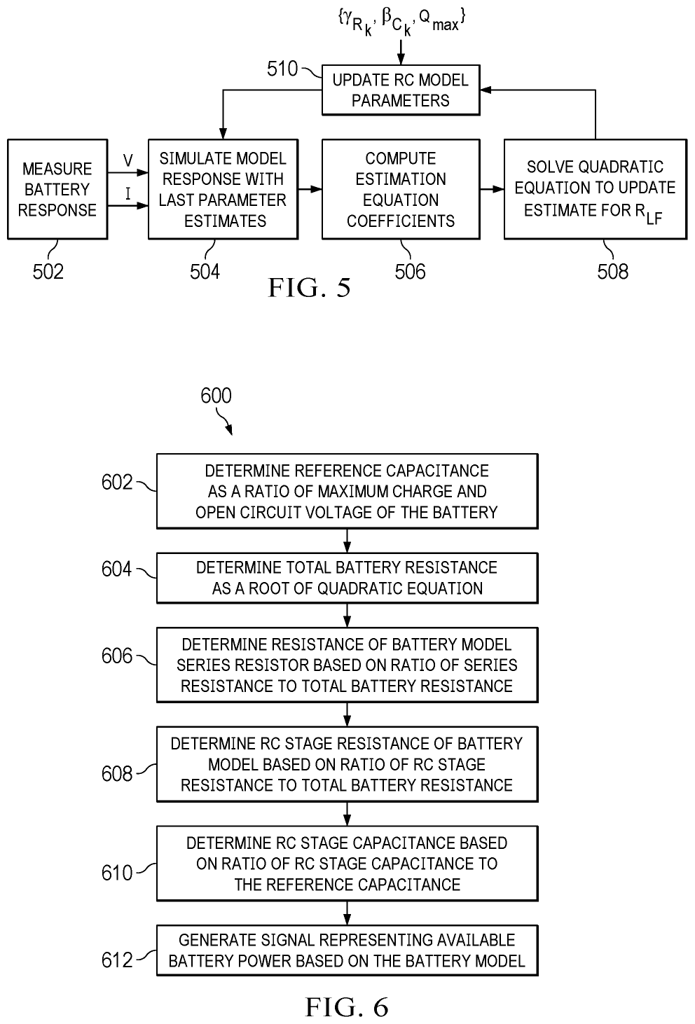

FIG. 5 is a block diagram of a higher-level view of battery model update operations in the battery gauge circuit 310. The battery model applied in FIG. 5 may be the model 100 or the model 200. In block 502, the battery gauge circuit 310 measures battery voltage and current. For example, the ADC 318 converts the voltage across the sense resistor 304 to a digital value as a measurement of battery current, and the ADC 314 and/or ADC 316 convert the voltage across a battery to a digital value as a measurement of battery voltage.

In block 504, the battery gauge circuit 310 (e.g., the battery model circuit 412) determines the response (e.g., capacitor voltages) of the battery model based on the measurements received from block 502, and current model parameter estimates (e.g., current resistance and capacitance values).

In block 506, the battery gauge circuit 310 (e.g., the R_{LF} estimation circuit 420) determines the coefficient values of the quadratic equation solved to determine the total resistance value of the battery model. The coefficient values may be determined based on the voltages provided by the battery model circuit 412, the measurements received from the block 502, and parameter values provided by the lookup tables 416.

In block 508, the battery gauge circuit 310 (e.g., the R_{LF} estimation circuit 420) solves the quadratic equation (e.g., equation (15)) to determine the total resistance value (R_{LF}) of the battery model.

In block 510, the battery gauge circuit 310 (e.g., the battery model circuit 412) applies R_{LF} provided by the R_{LF} estimation circuit 420 to determine updated values of the battery model parameters (e.g., resistance and capacitance values). For example, the battery model circuit 412 may solve equations (20)-(23) and (30) to determine the resistance and capacitance values.

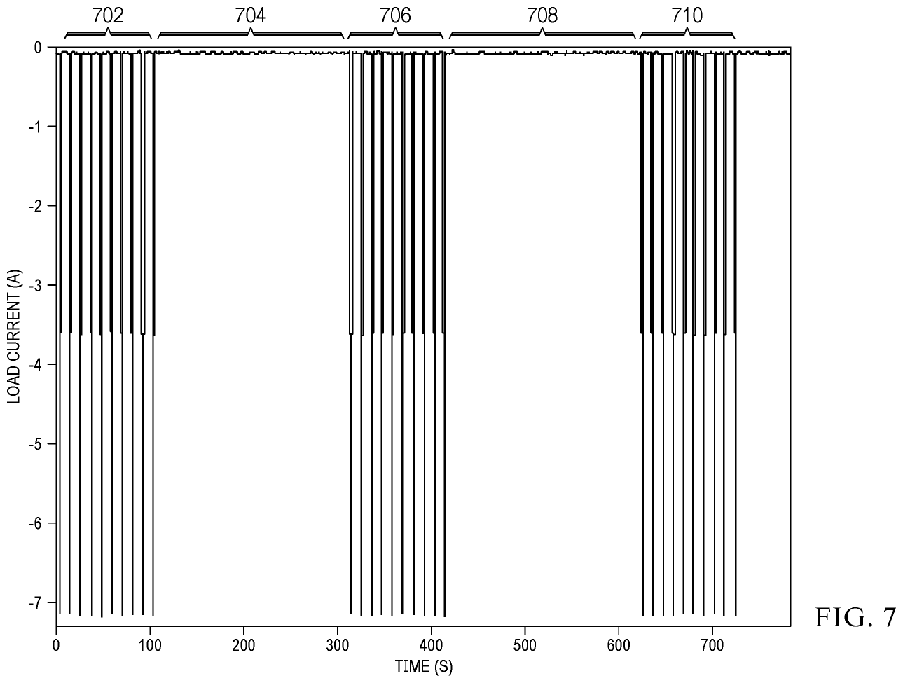

FIG. 6 is a flow diagram for an example method 600 for updating battery model parameters. Though depicted sequentially as a matter of convenience, at least some of the actions shown can be performed in a different order and/or performed in parallel. Additionally, some implementations may perform only some of the actions shown. Operations of the method 600 may be performed by the battery gauge circuit 310.

In step 602, the battery gauge circuit 310 determines a value of reference capacitance. The battery gauge circuit 310 may determine the value of reference capacitance as a ratio of maximum charge to open circuit voltage of the battery. For example, the battery gauge circuit 310 may determine the value of reference capacitance according to equation (25) or equation (26).

In step 604, the battery gauge circuit 310 determines a value of total battery resistance as a root of quadratic equation. For example, the battery gauge circuit 310 may solve the equation (15), (16), (17), or (31) to determine the roots of the quadratic equation, and select one of the roots to be the total resistance of the battery model.

In step 606, the battery gauge circuit 310 determines resistance of the battery model series resistor (resistor 104) based on a ratio of the resistor 104 to the total resistance of the battery model. For example, the battery gauge circuit 310 may determine the resistance value of the resistor 104 according to equation (20).

In step 608, the battery gauge circuit 310 determines the resistances of the battery model RC stage resistors (resistors 116, 120, 124) based on ratios of the resistances to the total resistance of the battery model. For example, the battery gauge circuit 310 may determine the resistance values of the resistors 116, 120, 124 according to equations (21), (22), and (23).

In step 610, the battery gauge circuit 310 determines the capacitances of the battery model RC stage capacitors (capacitors 118, 122, 126) based on ratios of the capacitances to the reference capacitance determined in step 602. For example, the battery gauge circuit 310 may determine the resistance values of the capacitors 118, 122, 126 according to equation (27).

In step 612, the battery gauge circuit 310 generates a signal representing available energy of the battery (e.g., battery SoC) based on the battery model. A control circuit coupled to the battery gauge circuit 310 may receive and apply the signal to control the energy use of a load circuit. For example, the control circuit may cause the load circuit coupled to the battery to reduce energy consumption (e.g., operate in a reduced power state) based on the signal indicating that the available energy of the battery is below a threshold value.

FIG. 7 is a graph of example load current pulses in an application. The application may be an electrical motor application, such as a power tool, or other application that intermittently draws current from the battery. In the intervals 704 and 708, the load current drawn from a battery is relatively low. In the intervals 702, 704, and 706, the load current drawn from the battery increases in relatively high current pulses. Accordingly, the rate at which current is drawn from the battery varies significantly.

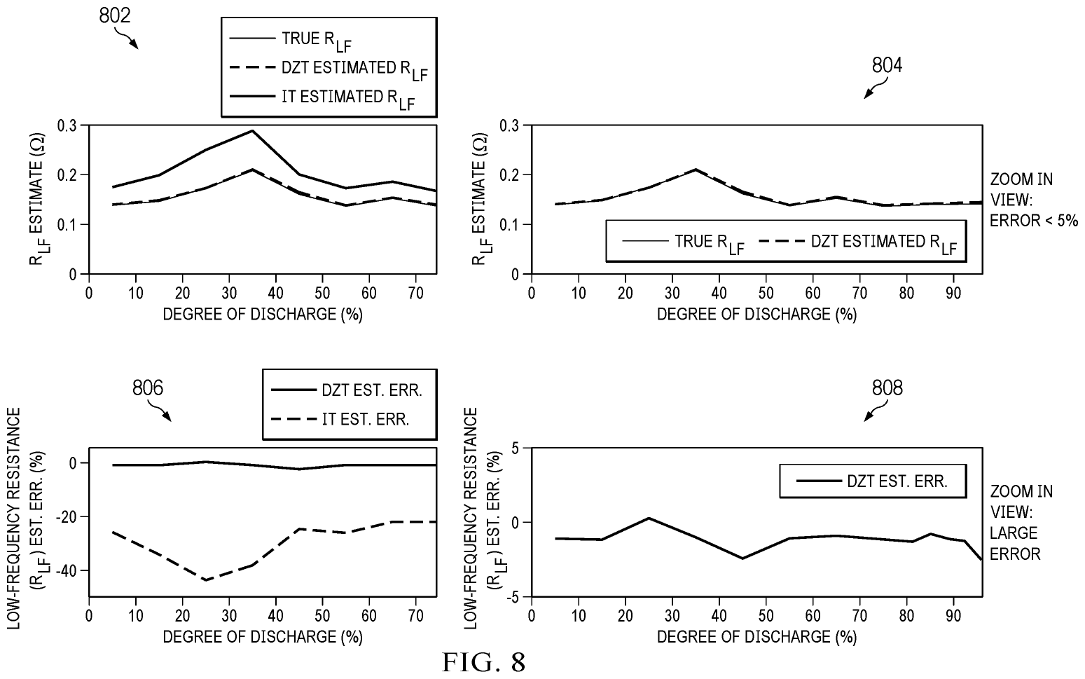

FIG. 8 shows graphs comparing total resistance (R_{LF}) of a battery determined using the battery gauge circuit 310 (DZT (dynamic impedance tracking) estimated R_{LF}) and total resistance of the battery determined using a series resistor-capacitor battery model (IT (impedance tracking) estimated R_{LF}) with the load current pulses of FIG. 7. The graph 802 shows the true R_{LF} of the battery, the R_{LF} of the battery determined by the battery gauge circuit 310, and the R_{LF} of the battery determined using the series resistor-capacitor battery model. Graph 802 shows that the R_{LF} of the battery determined by the battery gauge circuit 310 closely matches the true R_{LF} of the battery as the battery is discharged, while the R_{LF} of the battery determined using the series resistor-capacitor battery model deviates substantially from the true R_{LF}. The graph 804 is a magnified view of the true R_{LF} of the battery and the R_{LF} of the battery determined by the battery gauge circuit 310, showing that the R_{LF} of the battery determined by the battery gauge circuit 310 closely matches the true R_{LF} of the battery as the battery is discharged.

Graph 806 shows percent error of the R_{LF} of the battery determined by the battery gauge circuit 310 and of the R_{LF} of the battery determined using the series resistor-capacitor battery model relative to the true R_{LF}. The error of the R_{LF} determined by the battery gauge circuit 310 is relatively low (e.g., less than 5%), while the error of the R_{LF} determined using the series resistor-capacitor battery model ranges from about 20% to greater than 40%. Graph 808 is a magnified view of the percent error of the R_{LF} of the battery determined by the battery gauge circuit 310 showing less than 5% error at all levels of battery charge.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes.

For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit, comprising:
a processing circuit configured to:
model a battery using a battery model including: a voltage terminal, an RC stage having a first resistor and a first capacitor in parallel, a second resistor, a second capacitor and a ground terminal, in which the second resistor is coupled between the voltage terminal and the RC stage; the RC stage is coupled between the second resistor and the second capacitor, and the second capacitor is coupled between the RC stage and the ground terminal;
determine a first resistance of the first resistor based on a first ratio of the first resistance to a total battery resistance; and
determine a second resistance of the second resistor based on a second ratio of the second resistance to the total battery resistance; and
determine the total battery resistance.

2. The circuit of claim 1, wherein the processing circuit is configured to:
determine a first capacitance of the first capacitor based on a ratio of the first capacitance to a reference capacitance; and
determine the reference capacitance as a ratio of a maximum battery charge to an open circuit voltage.

3. The circuit of claim 1, wherein:
the RC stage is a first RC stage; and
the processing circuit is configured to:
provide the battery model as including a second RC stage having a third resistor and a third capacitor in parallel, in which the second RC stage is coupled between the first RC stage and the second capacitor; and
determine a third resistance of the third resistor based on a third ratio of the third resistance to the total battery resistance.

4. The circuit of claim 3, wherein the processing circuit is configured to:
determine a third capacitance of the third capacitor based on a ratio of the third capacitance to a reference capacitance; and
determine the reference capacitance as a ratio of a maximum battery charge to an open circuit voltage.

5. The circuit of claim 3, wherein the processing circuit is configured to:
provide the battery model as including a third RC stage having a fourth resistor and a fourth capacitor in parallel, in which the third RC stage is coupled between the second RC stage and the second capacitor; and
determine a fourth resistance of the fourth resistor based on a fourth ratio of the fourth resistance to the total battery resistance.

6. The circuit of claim 5, wherein the processing circuit is configured to:
determine a fourth capacitance of the fourth capacitor based on a ratio of the fourth capacitance to a reference capacitance.

7. The circuit of claim 1, wherein the processing circuit is configured to determine the total battery resistance as a root of a quadratic equation.

8. The circuit of claim 7, wherein the processing circuit is configured to select the root of the quadratic equation closest to a previous value of the total battery resistance.

9. The circuit of claim 7, wherein the processing circuit is configured to reject a value of the total battery resistance outside of range of resistance values based on prior values of the total battery resistance.

10. The circuit of claim 1, wherein the processing circuit is configured to:
determine the first resistance based on a first exponential function responsive to a measured temperature below a threshold;
determine the first resistance based on a second exponential function responsive to the measured temperature above the threshold;
determine the second resistance based on a third exponential function responsive to the measured temperature below a threshold; and
determine the second resistance based on a fourth exponential function responsive to the measured temperature above the threshold.

11. A method comprising:
determining a first resistance of a first resistor of a battery model based on a first ratio of the first resistance to a total battery resistance, in which the first resistor is coupled between a voltage terminal of the battery model and an RC stage of the battery model;
determining a second resistance of a second resistor of the battery model based on a second ratio of the second resistance to the total battery resistance, in which the second resistor is coupled in parallel with a first capacitor in the RC stage and the RC stage is coupled between the first resistor and a second capacitor of the battery model;
determining a reference capacitance as a ratio of a maximum charge of a battery to an open circuit voltage of the battery;
determining a first capacitance of the first capacitor based on a third ratio of the first capacitance to the reference capacitance;
determining the total battery resistance as a root of a quadratic equation; and
generating a signal representing power available in the battery based on the battery model.

12. The method of claim 11, wherein:
the RC stage is a first RC stage; and
the method includes:
determining a third resistance of a third resistor of the battery model based on a third ratio of the third resistance to the total battery resistance, in which the third resistor is coupled in parallel with a third capacitor in a second RC stage and the second RC stage is coupled between the first RC stage and the second capacitor.

13. The method of claim 12, further comprising determining a third capacitance of the third capacitor based on a fourth ratio of the third capacitance to the reference capacitance.

14. The method of claim 12, further comprising:
determining a fourth resistance of a fourth resistor of the battery model based on a fourth ratio of the fourth resistance to the total battery resistance, in which the fourth resistor is coupled in parallel with a fourth capacitor in a third RC stage and the third RC stage is coupled between the second RC stage and the second capacitor.

15. The method of claim 14, further comprising determining a fourth capacitance of the fourth capacitor based on a fifth ratio of the fourth capacitance to the reference capacitance.

16. The method of claim 11, further comprising selecting the root of the quadratic equation closest to a previous value of the total battery resistance.

17. The method of claim 11, further comprising rejecting a value of the total battery resistance outside of range of resistance values based on prior values of the total battery resistance.

18. The method of claim 11, further comprising:
determining the first resistance based on a first exponential function responsive to a measured temperature below a threshold;
determining the first resistance based on a second exponential function responsive to the measured temperature above the threshold;
determining the second resistance based on a third exponential function responsive to the measured temperature below a threshold; and
determining the second resistance based on a fourth exponential function responsive to the measured temperature above the threshold.

19. A system comprising:
a battery;
a battery gauge circuit coupled to the battery, the battery gauge circuit including:
a processing circuit configured to:
model the battery using a battery model including: a voltage terminal, an RC stage having a first resistor and a first capacitor in parallel, a second resistor, a second capacitor and a ground terminal, in which the second resistor is coupled between the voltage terminal and the RC stage; the RC stage is coupled between the second resistor and the second capacitor, and the second capacitor is coupled between the RC stage and the ground terminal;
determine a first resistance of the first resistor based on a first ratio of the first resistance to a total battery resistance; and
determine a second resistance of the second resistor based on a second ratio of the second resistance to the total battery resistance;
determine a reference capacitance as a ratio of a maximum charge of the battery to an open circuit voltage of the battery;
determine a first capacitance of the first capacitor based on a third ratio of the first capacitance to the reference capacitance;
and
determine the total battery resistance as a root of a quadratic equation.

20. The system of claim 19, wherein:
the RC stage is a first RC stage; and
the processing circuit is configured to:
provide the battery model as including a second RC stage having a third resistor and a third capacitor in parallel, in which the second RC stage is coupled between the first RC stage and the second capacitor; and
determine a third resistance of the third resistor based on a third ratio of the third resistance to the total battery resistance; and
determine a third capacitance of the third capacitor based on a ratio of the third capacitance to a reference capacitance.

21. The system of claim 20, wherein the processing circuit is configured to:
provide the battery model as including a third RC stage having a fourth resistor and a fourth capacitor in parallel, in which the third RC stage is coupled between the second RC stage and the second capacitor;
determine a fourth resistance of the fourth resistor based on a fourth ratio of the fourth resistance to the total battery resistance; and
determine a fourth capacitance of the fourth capacitor based on a ratio of the fourth capacitance to the reference capacitance.
